(19) United States
(12) Patent Application Publication
(10) Pub. No.: US 2023/0162949 A1
(43) Pub. Date: May 25, 2023

(54) APPARATUS FOR PROCESSING SUBSTRATE

(71) Applicant: SEMES CO., LTD., Chungcheongnam-do (KR)

(72) Inventors: Seung Hoon JEON, Gyeonggi-do (KR); Loung Sue CHANG, Chungcheongnam-do (KR); Jung Yoon YANG, Chungcheongnam-do (KR); Sun Ryum LEE, Chungcheongnam-do (KR); In Seong LIM, Chungcheongnam-do (KR); Kyoung Rae LEE, Chungcheongnam-do (KR)

(21) Appl. No.: 17/944,190

(22) Filed: Sep. 14, 2022

(30) Foreign Application Priority Data
Nov. 19, 2021 (KR) 10-2021-0160758

(51) Int. Cl. H01J 37/32

(52) U.S. Cl. CPC H01J 37/3222; H01J 2237/327

(57) ABSTRACT

An apparatus for processing a substrate is provided. The apparatus comprises a process chamber configured to define an interior space for internally processing a substrate, a substrate support unit configured to support the substrate in the interior space, a dielectric plate disposed above the substrate support unit, an antenna unit disposed over or above the dielectric plate, shaped into a frustum, having a truncated cone or prismoidal shape, and including a through-hole, a microwave application unit configured to apply microwaves to the antenna unit, and a slow-wave plate disposed on the antenna unit.

### CROSS-REFERENCE TO RELATED APPLICATION

This application claims priority from Korean Patent Application No. 10-2021-0160758 filed on Nov. 19, 2021 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to an apparatus for processing a substrate.

### 2. Description of the Related Art

Plasma is generated by a very high temperature, a strong electric field, or radio-frequency (RF) electromagnetic fields, and refers to an ionized gas state composed of ions, electrons, radicals, and the like. Semiconductor device manufacturing utilizes plasma in carrying out various processes.

In general, a substrate processing apparatus for generating plasma with microwaves utilizes an antenna and a dielectric plate to transmit the microwaves internally of a chamber in which a substrate is arranged.

### SUMMARY

Aspects of the present disclosure provide a substrate processing apparatus that transmits focused microwaves to a substrate.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided an apparatus for processing a substrate, including a process chamber configured to define an interior space for internally processing a substrate, a substrate support unit configured to support the substrate in the interior space, a dielectric plate disposed above the substrate support unit, an antenna unit disposed over or above the dielectric plate, shaped into a frustum, having a truncated cone or prismoidal shape, and including a through-hole, a microwave application unit configured to apply microwaves to the antenna unit, and a slow-wave plate disposed on the antenna unit.

The antenna unit may have a bottom end that is in contact with an edge of the dielectric plate, and the apparatus for processing a substrate may further include an air gap interposed between the antenna unit and the dielectric plate.

The slow-wave plate may surround the outer surfaces of the antenna unit.

The antenna unit may be shaped into a truncated cone.

The antenna unit may be shaped into a truncated triangular pyramid.

The antenna unit may have first, second, and third side surfaces which have a common inclination with respect to the top surface of the dielectric plate.

The antenna unit may have side surfaces formed with a plurality of slots.

The antenna unit may have a trapezoidal cross section cut in a direction perpendicular to the top surface of the dielectric plate.

The antenna unit may have varying cross-sections cut in a direction parallel to the top surface of the dielectric plate to provide gradually increasing cross-sections from the top to bottom ends of the antenna unit.

According to another aspect of the present disclosure, there is provided an apparatus for processing a substrate, including a process chamber configured to define an interior space for internally processing a substrate, a substrate support unit configured to support the substrate in the interior space, a dielectric plate disposed above the substrate support unit, an antenna unit disposed over or above the dielectric plate and including side surfaces inclined with respect to a top surface of the dielectric plate, and a microwave application unit configured to apply microwaves to the antenna unit. Here, the antenna unit has a top end that is connected to the bottom end of the microwave application unit, the side surfaces of the antenna unit have a bottom end that is in contact with an edge of the dielectric plate, and the bottom end of the antenna unit is larger than the top end of the antenna unit in cross-section as taken in a direction parallel to the top surface of the dielectric plate.

The side surfaces of the antenna unit may be inclined and connected to the top surface of the dielectric plate at an inclination angle of less than 90 degrees.

The apparatus for processing a substrate may further include a through-hole formed between the top end of the antenna unit and the bottom end of the antenna unit.

The apparatus for processing a substrate may further include a slow-wave plate disposed on the antenna unit and surrounding the inclined side surfaces of the antenna unit.

The antenna unit may have a trapezoidal cross section cut in a direction perpendicular to the top surface of the dielectric plate.

The apparatus for processing a substrate may further include an air gap interposed between the antenna unit and the dielectric plate.

According to yet another aspect of the present disclosure, there is provided an apparatus for processing a substrate, including a process chamber configured to define an interior space for internally processing a substrate, a substrate support unit configured to support the substrate in the interior space, a dielectric plate disposed above the substrate support unit, an antenna unit disposed over or above the dielectric plate and including side surfaces inclined with respect to a top surface of the dielectric plate, and a microwave application unit configured to apply microwaves to the antenna unit. Here, the antenna unit has a trapezoidal cross section cut in a direction perpendicular to the top surface of the dielectric plate.

The antenna unit may have the side surfaces inclined and formed with a plurality of slots.

The apparatus for processing a substrate may further include a slow-wave plate disposed on the antenna unit and surrounding the inclined side surfaces of the antenna unit.

The antenna unit may have varying cross-sections cut in a direction parallel to the top surface of the dielectric plate to provide gradually increasing cross-sections from the top to bottom ends of the antenna unit.

The apparatus for processing a substrate may further include an air gap between the antenna unit and the dielectric plate.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram illustrating a substrate processing apparatus 10 according to at least one embodiment of the present disclosure.

FIG. 2 is a diagram illustrating an antenna of the substrate processing apparatus 10 according to at least one embodiment of the present disclosure.

FIG. 3 is a diagram for explaining a substrate processing method performed by a substrate processing according to at least one embodiment of the present disclosure.

FIG. 4 is a plan view of an antenna and a substrate of a substrate processing apparatus according to at least one embodiment of the present disclosure.

FIG. 5 is a diagram illustrating an antenna of a substrate processing apparatus according to another embodiment of the present disclosure.

FIG. 6 is a diagram illustrating an antenna of a substrate processing apparatus according to yet another embodiment of the present disclosure.

FIG. 7 is a diagram illustrating an antenna of a substrate processing apparatus according to yet another embodiment of the present disclosure.

REFERENCE NUMERALS

| | |
|---|---|
| 10: substrate processing apparatus | 100: process chamber |
| 101: processing space | 102: exhaust hole |
| 105: gas supply hole | 110: body |
| 120: cover | 131: exhaust line |
| 200: substrate support unit | 210: support plate |
| 220: heater | 230: support shaft |
| 300: gas supply unit | 400: microwave application unit |
| 410: microwave generator | 420: first waveguide |
| 430: second waveguide | 432: outer conductor |
| 434: inner conductor | 440: phase converter |
| 450: matching network | 500: antenna unit |
| 501-503: first-third side surfaces | 510: slot |
| 520: side surfaces | 600: slow-wave plate |
| 700: dielectric plate | AG: air gap |
| W: substrate | |

### DETAILED DESCRIPTION OF THE EMBODIMENTS

Advantages and features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the present disclosure will only be defined by the appended claims.

It will also be understood that when an element or a layer is referred to as being “on” another element or layer, it can be not only directly on the other element or layer, but also indirectly thereon with intervening elements or layers being present. In contrast, when an element is referred to as being “directly on” another element, there are no intervening elements present.

Spatially relative terms, such as “below,” “beneath,” “lower,” “above,” “upper,” and the like, may be used herein for ease of description to convey one element's or feature's relationship to another element(s) or feature(s) as illustrated in the drawings. It will be understood that the spatially relative terms are intended to encompass different orientations of the device in use or operation in addition to the orientation depicted in the drawings. For example, when a device in the drawings is turned over, elements described as “below” or “beneath” other elements or features would then be oriented “above” the other elements or features. Thus, the illustrative term “below” can encompass both an orientation of above and below. The device may be otherwise oriented (rotated 90 degrees or at other orientations), and the spatially relative descriptors used herein may be interpreted accordingly.

It will be understood that, although the terms first, second, etc. may be used herein to describe various elements, components, and/or sections, these elements, components, and/or sections should not be limited by these terms. These terms are only used to distinguish one element, component, or section from another element, component, or section. Thus, a first element, first component, or first section discussed below could be termed a second element, second component, or second section without departing from the teachings of the present disclosure.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, some embodiments of the present disclosure will be described in detail with reference to the accompanying drawings. In the following description, like reference numerals designate like elements, although the elements are shown in different drawings. Further, in the following description of some embodiments, a detailed description of related known components and functions when considered to obscure the subject of the present disclosure will be omitted for the purpose of clarity and for brevity.

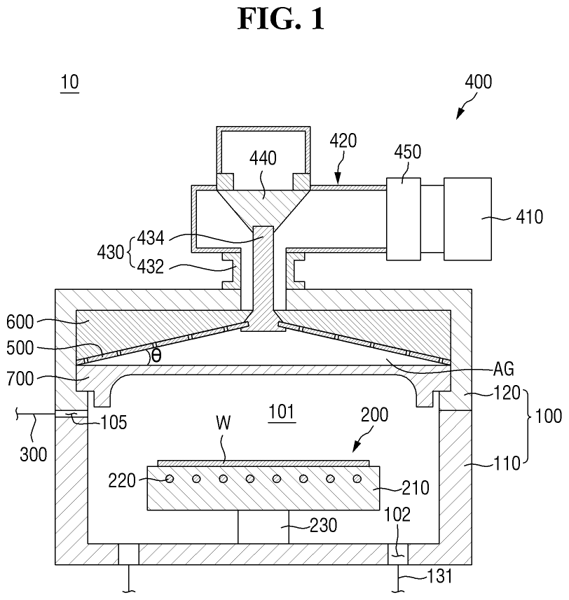

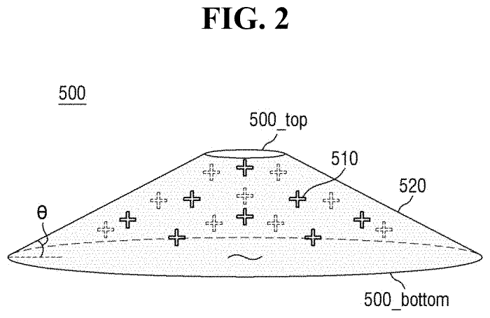

FIG. 1 is a diagram illustrating a substrate processing apparatus 10 according to at least one embodiment of the present disclosure. FIG. 2 is a diagram illustrating an antenna of the substrate processing apparatus 10 according to at least one embodiment of the present disclosure.

Referring to FIGS. 1 and 2, the substrate processing apparatus 10 includes a process chamber 100, a substrate support unit 200, a gas supply unit 300, a microwave application unit 400, an antenna unit 50, a slow-wave plate 600, and a dielectric plate 700.

The process chamber 100 is internally formed with a processing space 101 which is provided as a space in which a substrate W is processed. The process chamber 100 includes a body 110 and a cover 120. The body 110 has open upper surfaces and is internally formed with a space. The cover 120 is placed on the upper end of the body 110 and seals the open upper surfaces of the body 110. The cover 120 has a lower end formed with an internal step to provide the process chamber 100 with an upper space that is larger and a lower space that is smaller in radius.

The process chamber 100 has a bottom surface that may be formed with an exhaust hole 102. The exhaust hole 102 is connected to an exhaust line 131. By exhausting through the exhaust line 131, the inside of the process chamber 100 may be maintained at a pressure lower than normal pressure. Additionally, reaction by-products generated during the process and gas remaining in the process chamber 100 may be discharged to the outside through the exhaust line 131.

Although not shown in FIG. 1, a substrate entrance may be formed on one sidewall of the process chamber 100. The substrate entrance may be opened and closed by a door.

The substrate support unit 200 supports the substrate W in the processing space 140. The substrate support unit 200 includes a support plate 210, a heater 220, and a support shaft 230.

The support plate 210 has a predetermined thickness and is provided as a disk having a larger radius than the substrate W. The substrate W is placed on the upper surface of the support plate 210. According to at least one embodiment, the support plate 210 is not provided with a structure for fixing the substrate W, and the substrate W is put up for the process while being placed on the upper surface of the support plate 210. Alternatively, the support plate 210 may be provided as an electrostatic chuck for fixing the substrate W by using an electrostatic force or as a chuck for fixing the substrate W by using a mechanical clamping method.

Multiple lift pins are provided and are respectively located in pin holes (not shown) formed in the support plate 210. The lift pins move in the vertical direction along the pin holes and may load the substrate W onto the support plate 210 or unload the substrate W placed on the support plate 210.

The heater 220 is provided inside the support plate 210. The heater 220 is provided as a spiral coil and may be embedded in the support plate 210 at uniform intervals. The heater 220 is connected to an external power source (not shown) and generates heat by resisting current applied from the external power source. The generated heat is transferred to the substrate W through the support plate 210 and heats the substrate W to a predetermined temperature.

The support shaft 230 is positioned under the support plate 210 and supports thereof.

A gas supply unit 300 supplies a process gas to the processing space 140. Although not shown in FIG. 1, the gas supply unit 300 may include a gas storage unit, a valve, and a gas supply line. The valve may open and close the gas supply line and regulate the supply flow rate of the process gas. The gas supply unit 300 may supply the process gas stored in the gas storage unit into the process chamber 100 through a gas supply hole 105 formed in a sidewall of the process chamber 100 and through a gas supply line. Multiples of the gas supply hole 105 may be provided.

The microwave application unit 400 applies microwaves to the antenna unit 500. The microwave application unit 400 includes a microwave generator 410, a first waveguide 420, a second waveguide 430, a phase converter 440, and a matching network 450.

The microwave generator 410 generates microwaves needed to excite the process gas into a plasma state.

The first waveguide 420 is connected to the microwave generator 410 and is internally formed with a passage. The microwaves generated by the microwave generator 410 are transmitted to the phase converter 440 along the first waveguide 420.

The second waveguide 430 includes an outer conductor 432 and an inner conductor 434.

The outer conductor 432 extends downward in the vertical direction from the end of the first waveguide 420 and is internally formed with a passage. The outer conductor 432 has an upper end connected to the lower end of the first waveguide 420 and a lower end connected to the upper end of the cover 120.

The inner conductor 434 is located within the outer conductor 432. The inner conductor 434 is provided as a cylindrical rod, and the longitudinal direction thereof is arranged parallel to the vertical direction. The inner conductor 434 has its upper end fixedly inserted in the lower end of the phase converter 440. The inner conductor 434 extends downward and has its lower end located inside the process chamber 100. The lower end of the inner conductor 434 is fixedly coupled to the center of the antenna unit 500. Specifically, the lower end of the inner conductor 434 is coupled to an antenna-unit top 500_top of the antenna unit 500. The inner conductor 434 may be provided by sequentially coating a first plating layer and a second plating layer on a copper rod. According to at least one embodiment, the first plating layer may be made of nickel (Ni), and the second plating layer may be made of gold (Au). Microwaves are mainly propagated through the first plating film to the antenna unit 500.

The phase-converted microwave in the phase converter 440 is transmitted to the antenna unit 500 along the second waveguide 430.

The phase converter 440 is provided at a point where the first waveguide 420 connects to the second waveguide 430 and changes the phase of the microwave. The phase converter 440 may be provided in the shape of a cone having a pointed bottom. The phase converter 440 propagates the microwave transmitted from the first waveguide 420 to the second waveguide 430 with the microwave mode converted. The phase converter 440 may convert the microwave from a transverse electric (TE) mode to a transverse electromagnetic (TEM) mode.

The matching network 450 is provided in the first waveguide 420. The matching network 450 matches the microwave propagating through the first waveguide 420 to a predetermined frequency.

The antenna unit 500 may be arranged over or above the substrate support unit 200 and the dielectric plate 700 to face the support plate 210. The antenna-unit top 500_top may be connected to the inner conductor 434 of the second waveguide 430. Specifically, the antenna-unit top 500_top may surround the inner conductor 434, and the lower end of the inner conductor 434 may be fitted into a hole defined by the antenna-unit top 500_top. The antenna unit 500 has an antenna-unit bottom 500_bottom that may be in contact an edge portion of the top surface of the dielectric plate 700.

The antenna unit 500 may be shaped into a frustum, having a truncated cone or prismoidal shape. For example, the antenna unit 500 may be provided in a thin truncated cone shape. The antenna-unit top 500_top may be unpointed and may have a flat circular shape in cross section of a cone shape that is cut midway.

The antenna-unit bottom 500_bottom has a larger radius than the antenna-unit top 500_top. Specifically, the cross-sectional area gradually increases from the antenna-unit top 500_top to the antenna-unit bottom 500_bottom. Accordingly, side surfaces 520 of the antenna unit 500 interconnecting the antenna-unit top 500_top and the antenna-unit bottom 500_bottom may meet the top surface of the dielectric plate 700 at a certain angle θ. In other words, the antenna unit 500 is neither planar nor parallel to the top surface of the dielectric plate 700 but may incline. The certain angle formed between the side surfaces 520 of the antenna unit 500 and the top surface of the dielectric plate 700 may be varied according to embodiments.

The side surfaces 520 of the antenna unit 500 may be arranged in an inclined shape with respect to the top surface of the dielectric plate 700. Specifically, the side surfaces 520 of the antenna unit 500 do not perpendicularly meet the top surface of the dielectric plate 700, but the side surfaces 520 inclined at an angle of less than 90 degrees meet the top surface of the dielectric plate 700. A cross section of the antenna unit 500 cut perpendicular to the top surface of the dielectric plate 700 may have a trapezoidal shape.

The antenna unit 500 may have a truncated cone shape of a thin curved sheet in which a through-hole is formed between the antenna-unit top 500_top and the antenna-unit bottom 500_bottom.

The side surfaces 520 of the antenna unit 500 may be formed with a plurality of slots 510. For example, a plurality of slots 510 may be uniformly distributed on the side surfaces 520 of the antenna unit 500. For another example, over the side surfaces 520 of the antenna unit 500, the closer to the antenna-unit top 500_top, the more densely the slots 510 may be arranged, and the closer to the antenna-unit bottom 500_bottom, the more sparsely the slots 510 may be arranged. The plurality of slots 510 may be provided in a ‘+’ shape or an ‘×’ shape. However, the embodiments are not limited thereto, and the shape and arrangement of the slots 150 may be variously modified.

The slow-wave plate 600 is located on the antenna unit 500 and may be provided as a disk having predetermined thicknesses. The slow-wave plate 600 may have a radius corresponding to the inner side of the cover 120. The slow-wave plate 600 is provided with a dielectric material such as alumina or quartz. Microwaves propagated in the vertical direction through the inner conductor 434 proceed in the radial direction of the slow-wave plate 600. The microwave propagated to the slow-wave plate 600 has its wavelength compressed and is resonated. The slow-wave plate 600 may contact the upper surface of the antenna unit 500. Specifically, the lower surface of the slow-wave plate 600 may surround the outer surface of the antenna unit 500.

The dielectric plate 700 is positioned under the antenna unit 500 and may be provided as a disk having predetermined thicknesses. The dielectric plate 700 may be provided with a dielectric material such as alumina or quartz. The bottom surface of the dielectric plate 700 may have an inwardly concave or recessed surface. The dielectric plate 700 may have its bottom surface positioned at the same elevation as the lower end of the cover 120. The dielectric plate 700 may have its side formed to be stepped providing a middle portion with a larger radius than the lower ends thereof. The surface lower than the middle portion of the dielectric plate 700 may be placed on the stepped lower end of the cover 120. The lower end of the dielectric plate 700 may have a smaller radius than the lower end of the cover 120 and may maintain a predetermined distance from the lower end of the cover 120. The microwave is radiated through the dielectric plate 700 to the processing space 101 of the process chamber 100.

An air gap AG may be formed between the antenna unit 500 and the dielectric plate 700. Specifically, the antenna unit 500 and the dielectric plate 700 do not completely contact each other, which allows a space to be formed between the bottom of the antenna unit 500 and the top of the dielectric plate 700.

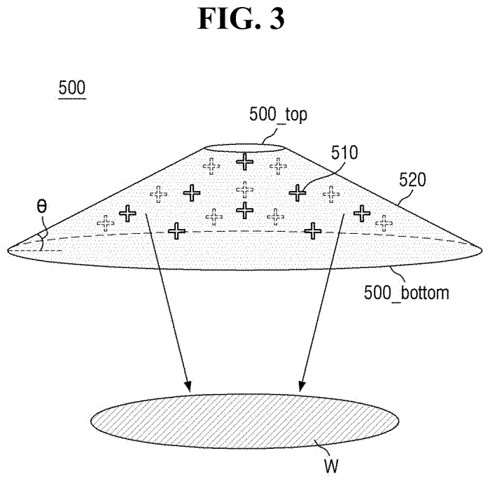

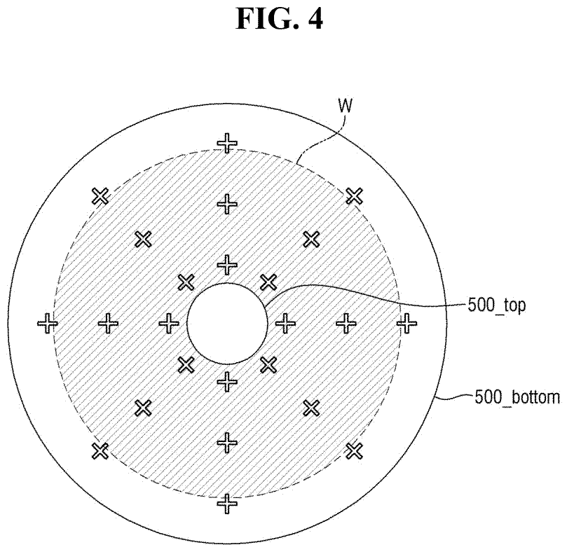

FIG. 3 is a diagram for explaining a substrate processing method performed by a substrate processing according to at least one embodiment of the present disclosure. FIG. 4 is a plan view of an antenna and a substrate of a substrate processing apparatus according to at least one embodiment of the present disclosure.

Referring to FIGS. 3 and 4, the antenna unit 500 may be disposed over the substrate W to overlap the same. In particular, the cross-sectional area of the antenna-unit top 500_top may be smaller than that of the substrate W, and the cross-sectional area of the antenna-unit bottom 500_bottom may be greater than that of the substrate W.

Microwaves passing through the antenna unit 500 shaped as a frustum are not transmitted perpendicularly to the substrate W but may be deflected while passing through the side surfaces 520 of the antenna unit 500. In other words, the microwaves transmitted through the side surfaces 520 of the antenna unit 500 that is not arranged parallel to the substrate W but at a specific angle θ with the substrate W are focused and delivered to the substrate W.

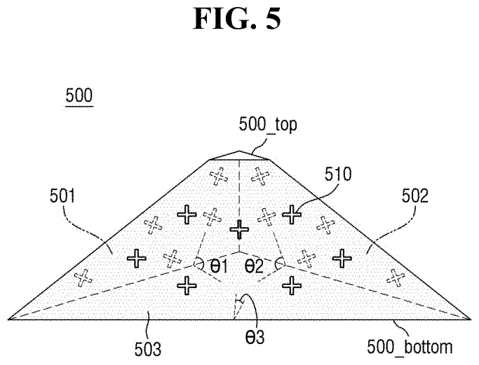

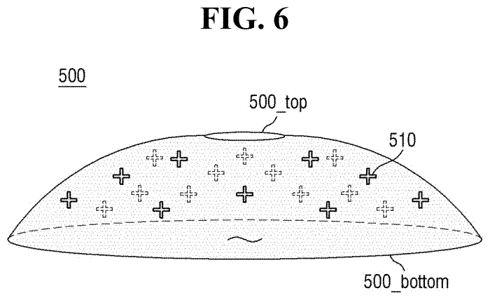

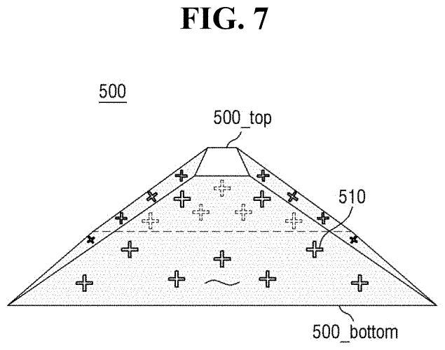

FIG. 5 is a diagram illustrating an antenna of a substrate processing apparatus according to another embodiment of the present disclosure. FIG. 6 is a diagram illustrating an antenna of a substrate processing apparatus according to yet another embodiment of the present disclosure. FIG. 7 is a diagram illustrating an antenna of a substrate processing apparatus according to yet another embodiment of the present disclosure. For the convenience of explanation, the following focuses on details different from those described with reference to FIG. 2.

Referring to FIG. 5, the antenna unit 500 may be shaped into a truncated triangular pyramid. Specifically, the antenna unit 500 may have first, second and third side surfaces 501 to 503. The first to third side surfaces 501 to 503 may have first, second and third angles θ1 to θ3 with respect to the top surface of the dielectric plate 700. For example, all of the first to third angles θ1 to θ3 may be the same. As another example, the first to third angles θ1 to θ3 may be different from each other. The first to third side surfaces 501 to 503 may not perpendicularly meet the top surface of the dielectric plate 700, but may meet the same at an acute angle smaller than 90 degrees.

The first to third side surfaces 501 to 503 may each have a trapezoidal shape.

The antenna unit 500 may have a triangular antenna-unit top 500_top and a triangular antenna-unit bottom 500_bottom. Accordingly, the antenna unit 500 may have an inner conductor 434 with a lower end that is triangular in cross section to conform and connect to the triangular antenna-unit top 500_top. The cross section of the triangular shape of the antenna-unit bottom 500_bottom is larger than the cross section of the substrate W.

The slow-wave plate 600 disposed over or above the antenna unit 500 may surround the first to third sides 501-503 of the antenna unit 500. For example, the slow-wave plate 600 may conformally contact the first to third side surfaces 501 to 503 of the antenna unit 500.

Referring to FIG. 6, the antenna unit 500 may have a dome shape with the top removed from the hemisphere. In this case, the antenna unit 500 may have a circular antenna-unit top 500_top and a circular antenna-unit bottom 500_bottom. A cross-section cut parallel to the top surface of the dielectric plate 700 gradually increases from the circular antenna-unit top 500_top to the circular antenna-unit bottom 500_bottom. The cross-section of the circular antenna-unit bottom 500_bottom is larger than that of the substrate W.

Referring to FIG. 7, the antenna unit 500 may be shaped into a truncated quadrangular pyramid with the top removed from the quadrangular pyramid. In this case, the antenna unit 500 may have a rectangular antenna-unit top 500_top and a rectangular antenna-unit bottom 500_bottom. The antenna unit 500 may have first to fourth side surfaces. The first to fourth side surfaces may have one or more certain angles with respect to the top surface of the dielectric plate 700. The first to fourth side surfaces may each meet the edge portion of the top surface of the dielectric plate 700 at an inclination angle with respect to the top surface of the dielectric plate 700.

From the rectangular antenna-unit top 500_top to the rectangular antenna-unit bottom 500_bottom, the quadrangle, which is a cross-section cut parallel to the top surface of the dielectric plate 700, gradually increases.

While some embodiments of the present disclosure have been particularly shown and described with reference to the accompanying drawings, it will be understood by those of ordinary skill in the art that various changes in form and details may be made therein without departing from the technical idea and scope of the present disclosure as defined by the following claims.

1. An apparatus for processing a substrate, comprising:
a process chamber configured to define an interior space for internally processing a substrate;
a substrate support unit configured to support the substrate in the interior space;
a dielectric plate disposed above the substrate support unit;
an antenna unit disposed over or above the dielectric plate, shaped into a frustum, having a truncated cone or prismoidal shape, and including a through-hole;
a microwave application unit configured to apply microwaves to the antenna unit; and
a slow-wave plate disposed on the antenna unit.

2. The apparatus of claim 1, wherein the antenna unit has a bottom end that is in contact with an edge of the dielectric plate, and
wherein the apparatus further comprising:
an air gap interposed between the antenna unit and the dielectric plate.

3. The apparatus of claim 1, wherein the slow-wave plate surrounds outer surfaces of the antenna unit.

4. The apparatus of claim 1, wherein the antenna unit is shaped into a truncated cone.

5. The apparatus of claim 1, wherein the antenna unit is shaped into a truncated triangular pyramid.

6. The apparatus of claim 1, wherein the antenna unit has first, second and third side surfaces which have a common inclination with respect to a top surface of the dielectric plate.

7. The apparatus of claim 1, wherein the antenna unit has side surfaces formed with a plurality of slots.

8. The apparatus of claim 1, wherein the antenna unit has a trapezoidal cross section cut in a direction perpendicular to a top surface of the dielectric plate.

9. The apparatus of claim 1, wherein the antenna unit has varying cross-sections cut in a direction parallel to a top surface of the dielectric plate to provide gradually increasing cross-sections from top to bottom ends of the antenna unit.

10. An apparatus for processing a substrate, comprising:
a process chamber configured to define an interior space for internally processing a substrate;
a substrate support unit configured to support the substrate in the interior space;
a dielectric plate disposed above the substrate support unit;
an antenna unit disposed over or above the dielectric plate and including side surfaces inclined with respect to a top surface of the dielectric plate; and
a microwave application unit configured to apply microwaves to the antenna unit,
wherein the antenna unit has a top end that is connected to a bottom end of the microwave application unit,
the side surfaces of the antenna unit have a bottom end that is in contact with an edge of the dielectric plate, and
the bottom end of the antenna unit is larger than the top end of the antenna unit in cross-section as taken in a direction parallel to the top surface of the dielectric plate.

11. The apparatus of claim 10, wherein the side surfaces of the antenna unit are inclined and connected to the top surface of the dielectric plate at an inclination angle of less than 90 degrees.

12. The apparatus of claim 10, further comprising:
a through-hole formed between the top end of the antenna unit and the bottom end of the antenna unit.

13. The apparatus of claim 10, further comprising:
a slow-wave plate disposed on the antenna unit and surrounding the side surfaces of the antenna unit, which are inclined.

14. The apparatus of claim 10, wherein the antenna unit has a trapezoidal cross section cut in a direction perpendicular to the top surface of the dielectric plate.

15. The apparatus of claim 10, further comprising:
an air gap interposed between the antenna unit and the dielectric plate.

16. An apparatus for processing a substrate, comprising:
a process chamber configured to define an interior space for internally processing a substrate;
a substrate support unit configured to support the substrate in the interior space;
a dielectric plate disposed above the substrate support unit;
an antenna unit disposed over or above the dielectric plate and including side surfaces inclined with respect to a top surface of the dielectric plate; and
a microwave application unit configured to apply microwaves to the antenna unit,
wherein the antenna unit has a trapezoidal cross section cut in a direction perpendicular to the top surface of the dielectric plate.

17. The apparatus of claim 16, wherein the antenna unit has the side surfaces inclined and formed with a plurality of slots.

18. The apparatus of claim 16, further comprising:
a slow-wave plate disposed on the antenna unit and surrounding the side surfaces of the antenna unit, which are inclined.

19. The apparatus of claim 16, wherein the antenna unit has varying cross-sections cut in a direction parallel to the top surface of the dielectric plate to provide gradually increasing cross-sections from top to bottom ends of the antenna unit.

20. The apparatus of claim 16, further comprising:
an air gap between the antenna unit and the dielectric plate.
